(19) United States
(12) Patent Application Publication
(10) Pub. No.: US 2026/0121633 A1
(43) Pub. Date: Apr. 30, 2026

(54) RF SWITCH DEVICE UTILIZING TRANSFORMERS AND OPERATING METHOD FOR THE SAME

(71) Applicant: ELECTRONICS AND TELECOMMUNICATIONS RESEARCH INSTITUTE, Daejeon (KR)

(72) Inventors: Sun Woo KONG, Daejeon (KR); Bong Hyuk Park, Daejeon (KR); Seung Hun Wang, Daejeon (KR); Hui Dong Lee, Daejeon (KR); Seunghyun Jang, Daejeon (KR); Jung Hwan Hwang, Daejeon (KR)

(21) Appl. No.: 19/003,624

(22) Filed: Dec. 27, 2024

(30) Foreign Application Priority Data
Dec. 29, 2023 (KR) 10-2023-0196507

(51) Int. Cl. H03K 17/51; H01F 38/00

(52) U.S. Cl. CPC H03K 17/51; H01F 38/00

(57) ABSTRACT

An RF switch device according to an exemplary embodiment includes: a primary inductor forming a primary coil of a transformer and connected to a first port; a first secondary inductor forming a part of a secondary coil of the transformer and connected to a second port; and a second secondary inductor forming another part of the secondary coil of the transformer and connected to a third port. The primary inductor includes: a first primary inductor covering a first region; and a second primary inductor covering a second region other than the first region. The second secondary inductor has a shape of a twisted loop having a twisted position between the first region and the second region so that a current flows in different directions in a first loop portion covering the first region and a second loop portion covering the second region.

### CROSS-REFERENCE TO RELATED APPLICATION

The present application claims a convention priority under 35 U.S.C. § 119 (a) based on Korean Patent Application No. 10-2023-0196507 filed on Dec. 29, 2023, the entire content of which is incorporated herein in its entirety by reference.

### BACKGROUND

### 1. Technical Field

The present disclosure relates to an RF switch used to effectively route an RF signal in a wireless communications system and, more particularly, to a switch structure for reducing an insertion loss in a selected path and enhancing an isolation from an unselected path.

### 2. Related Art

The description in this section merely provides background information of embodiments of the present disclosure and is not intended to specify prior arts of the present disclosure.

A RF switch, which is a circuit component widely used in a transmitter and receiver of a communication module, can perform a function of passing a RF signal, connecting a RF signal path to ground, or bypassing another circuit component. In addition, the RF switch may be used to change an operating frequency of an antenna, in which case the RF switch may be disposed between the antenna and an impedance element to connect or disconnect the impedance element to or from the antenna.

The RF switch is a device for selecting a signal transmission path to effectively route the RF signal in a wireless communications system. The RF switch may be used in a signal transmitting or receiving path in a certain frequency band and may select one of several signal paths to allow a passage of the signal or to block the signal. The usages or roles of the RF switch may be summarized as follows:
Signal path selection: The RF switch may select a particular path among various antennas or transmission lines to route the signal. For example, the RF switch may select an optimal antenna in a multiple antenna system or perform a switching among a plurality of transmission lines.
Signal blocking and reinforcement: The RF switch may block or reinforce a signal in a particular path to optimize the performance of the wireless communications system. For example, the RF switch may block an unnecessary signal component an environment where a strong interference occurs or reinforce the signal to increase a communication range.
Multiple operation mode and frequency band support: The RF switch may be adapted to various communication environments to support various wireless communication modes and frequency bands. This feature of the RF switch may be especially beneficial in system using multiple frequency bands or employing multiple protocols.

These usages or roles of the RF switch may improve the performance of wireless communications system and minimize a signal interference to enable stable and efficient communications.

### SUMMARY

In order for the RF switch to effectively perform the signal path selection, the signal blocking and reinforcement, and the multiple operation mode and frequency band support, it is desirable to reduce an insertion loss of the RF switch in a selected path and enhance an isolation from an unselected path.

A conventional RF switch used in a RF transmission stage typically employs a transistor. It is desirable to increase a size of the transistor to reduce the insertion loss of the RF switch when the RF switch operates to be in a transmission path while it is required to reduce size of the transistor to enhance the isolation from the transmission path when the RF switch operates to be in an isolated path. Since it is impossible to reduce the insertion loss and enhance the isolation simultaneously, the conventional RF switch has a drawback that there is a trade-off relationship between the insertion loss and the isolation.

To solve the above problem, the present disclosure provides a RF switch structure which employs a transformer utilizing a magnetic coupling instead of a transistor to achieve a high isolation and low insertion in a RF transmission path.

The present disclosure provides a RF switch structure of which function may expand from a switch to an amplifier based on a configuration allowing to combine additional signals.

According to an aspect of an exemplary embodiment, an RF switch device may include: a primary inductor forming a primary coil of a transformer and connected to a first port; a first secondary inductor forming a part of a secondary coil of the transformer and connected to a second port; and a second secondary inductor forming another part of the secondary coil of the transformer and connected to a third port.

The primary inductor may include: a first primary inductor covering a first region; and a second primary inductor covering a second region other than the first region.

The first secondary inductor may cover both the first region and the second region so that a loop current through the first secondary inductor flows with a same direction in the first region and the second region.

The second secondary inductor may have a shape of a twisted loop having a twisted position between the first region and the second region so that a current flows in different directions in a first loop portion covering the first region and a second loop portion covering the second region.

The first primary inductor may be magnetically coupled to either the first secondary inductor or the second secondary inductor in the first region. The second primary inductor may be magnetically coupled to either the first secondary inductor or the second secondary inductor in the second region.

A direction of a first loop current formed in the first region by the first primary inductor and a direction of a second loop current formed in the second region by the second primary inductor may be controlled to be the same as or opposite to each other.

Directions of a first magnetic flux formed in the first region and a second magnetic flux formed in the second region may be determined according to the direction of the first loop current and the direction of the second loop current, respectively.

In the RF switch device according to an exemplary embodiment of the present disclosure, the first port may be determined to be effectively coupled with either the second port or the third port for a signal passage depending on whether the directions of the first loop current and the second loop current are the same as each other or opposite to each other.

In the RF switch device according to an exemplary embodiment of the present disclosure, when the directions of the first loop current and the second loop current are the same as each other, a current component induced in the second secondary inductor by the first loop current and a current component induced in the second secondary inductor by the second loop current may be canceled, and the first port may be effectively coupled with the second port for the signal passage.

In the RF switch device according to an exemplary embodiment of the present disclosure, when the directions of the first loop current and the second loop current are opposite to each other, a current component induced in the first secondary inductor by the first loop current and a current component induced in the first secondary inductor by the second loop current may be canceled, and the first port may be effectively coupled with the third port for the signal passage.

The RF switch device according to an exemplary embodiment of the present disclosure may further include: a switching circuit connected to the first primary inductor and the second primary inductor to control the directions of the first loop current and the second loop current to be the same as each other or opposite to each other.

In the RF switch device according to an exemplary embodiment of the present disclosure, the directions of the first loop current and the second loop current may be controlled to be the same as each other when the switching circuit is in a first connection state.

In the RF switch device according to an exemplary embodiment of the present disclosure, the directions of the first loop current and the second loop current may be controlled to be opposite to each other when the switching circuit is in a second connection state.

In the RF switch device according to an exemplary embodiment of the present disclosure, the switching circuit may include: a first switching circuit configured to switch a connection polarity between the first port and the first primary inductor; and a second switching circuit configured to switch a connection polarity between the first port and the second primary inductor.

In the RF switch device according to an exemplary embodiment of the present disclosure, the primary inductor may further include: a third primary inductor covering a third region other than the first region and the second region; and a fourth primary inductor covering a fourth region other than the first through the third regions.

In such a case, the first secondary inductor may be configured to cover the first through the fourth regions.

Further, the second secondary inductor may have another twisted position between the third region and the fourth region so that a current flows in different directions in the third region and the fourth region.

In the RF switch device according to an exemplary embodiment of the present disclosure, in a state that the directions of the first loop current and the second loop current are determined, an input signal may be applied to the first port and an output signal is provided through the second port or the third port.

In the RF switch device according to an exemplary embodiment of the present disclosure, in a state that the directions of the first loop current and the second loop current are determined, an input signal may be applied to the second port or the third port and an output signal is provided through the first port.

According to another aspect of an exemplary embodiment, a method of operating an RF switch includes: selecting either a second port connected to a first secondary inductor or a third port connected to a second secondary inductor as a secondary side port to be effectively coupled for a signal passage to a primary inductor forming a primary coil of a transformer and connected to a first port; determining a direction of a first loop current flowing in a first primary inductor and a direction of a second loop current flowing in a second primary inductor based on the selected secondary side port, wherein the first primary inductor and the second primary inductor connected to the first port and included in the primary inductor; and determining an input port and an output port from the first port and the selected secondary side port.

In the method of operating the RF switch according to an exemplary embodiment of the present disclosure, the first primary inductor may cover a first region, and the second primary inductor may cover a second region. The first secondary inductor may cover both the first region and the second region so that a loop current through the first secondary inductor (A) 100 flows with a same direction in the first region and the second region. The second secondary inductor may have a twisted position between the first region and the second region so that the current flows in opposite directions in a first loop portion covering the first region and a second loop portion covering the second region.

The operation of determining the directions of the first loop current and the second loop current may include: when the second port is selected as the secondary side port, setting the directions of the first loop current and the second loop current to be the same as each other; and, when the third port is selected as the secondary side port, setting the directions of the first loop current and the second loop current to be opposite to each other.

The method of operating the RF switch according to an exemplary embodiment of the present disclosure may further include: determining a configuration for connecting the first primary inductor and the second primary inductor according to the directions of the first loop current and the second loop current.

The method of operating the RF switch according to an exemplary embodiment of the present disclosure, the operation of determining the configuration for connecting the first primary inductor and the second primary inductor may include: determining a connection state of a first switching circuit connecting the first port and the first primary inductor; and determining a connection state of a second switching circuit connecting the second port and the second primary inductor.

The method of operating the RF switch according to an exemplary embodiment of the present disclosure may further include: applying a signal to the input port.

An exemplary embodiment of the present disclosure may provide a high isolation performance between any two ports requiring the isolation among three ports provided in the RF switch device.

According to an exemplary embodiment of the present disclosure, an insertion loss and the isolation are not in a trade-off relationship, and the RF switch device may be implemented to achieve the high isolation as well as a low insertion loss simultaneously.

According to an exemplary embodiment of the present disclosure, the low insertion loss may be provided for a secondary inductor matching the magnetic flux direction with the primary inductor, and the high isolation performance may be provided for the secondary inductor associated with a magnetic flux opposite to the direction of the magnetic flux of the primary inductor.

According to an exemplary embodiment of the present disclosure, a MOS transistor may be connected to a primary side port and the structure of the RF switch of the present disclosure may be used as a load or an input matching stage of an amplifier, so that the RF switch may further perform an amplification function.

According to an exemplary embodiment of the present disclosure, a number of segments in the primary inductor may be increased to enhance the power coupling between the inductors.

### BRIEF DESCRIPTION OF THE DRAWINGS

In order that the disclosure may be well understood, there will now be described various forms thereof, given by way of example, reference being made to the accompanying drawings, in which:

FIG. 1 is a schematic diagram illustrating roles of an RF front end and an RF switch according to an exemplary embodiment of the present disclosure;

FIG. 2 is a schematic diagram illustrating an equivalent circuit showing a connection configuration of a conventional RF switch;

FIG. 3 is a schematic diagram illustrating a conventional switch structure employing a transmission line;

FIG. 4 is a schematic diagram illustrating an RF switch device utilizing a transformer according to an exemplary embodiment of the present disclosure;

FIG. 5 is an exploded view of the RF switch device shown in FIG. 4 to facilitate understanding of a shape of each inductor element in the RF switch device;

FIG. 6 is a perspective view of the RF switch device shown in FIG. 4 to facilitate understanding of a three-dimensional shape of the RF switch device;

FIG. 7 is a conceptual diagram illustrating a first embodiment of an operation of the RF switch device according to an exemplary embodiment of the present disclosure, in which the loop current directions of a first primary inductor and a second primary inductor are the same as each other and a signal is input through a primary side port;

FIG. 8 is a conceptual diagram illustrating a second embodiment of an operation of the RF switch device according to an exemplary embodiment of the present disclosure, in which the loop current directions of the first primary inductor and the second primary inductor are opposite to each other and a signal is input through the primary side port;

FIG. 9 is a conceptual diagram illustrating a third embodiment of an operation of the RF switch device according to an exemplary embodiment of the present disclosure, in which the loop current directions of the first primary inductor and the second primary inductor are the same as each other and an input signal is applied through the secondary side port;

FIG. 10 is a conceptual diagram illustrating a fourth embodiment of an operation of the RF switch device according to an exemplary embodiment of the present disclosure, in which the loop current directions of the first primary inductor and the second primary inductor are opposite to each other and the input signal is applied through the secondary side port;

FIG. 11 is a conceptual diagram illustrating the RF switch device according to another exemplary embodiment of the present disclosure, in which a number of segments in a primary inductor is increased to enhance power coupling between the inductors;

FIG. 12 is a conceptual diagram illustrating the RF switch device according to an exemplary embodiment of the present disclosure, in which switching circuits connecting the primary inductor segments to the primary side port are incorporated;

FIG. 13 is a conceptual diagram illustrating a connection configuration between the primary inductor segments compatible with the first embodiment and the third embodiment of the operation of the RF switch device of the present disclosure;

FIG. 14 is a graph showing results of electromagnetic simulations according to frequency bands for the embodiment of FIG. 13;

FIG. 15 is a conceptual diagram illustrating a connection configuration between the primary inductor segments compatible with the second embodiment and the fourth embodiment of the operation of the RF switch device of the present disclosure;

FIG. 16 is a graph showing results of electromagnetic simulations according to frequency bands for the embodiment of FIG. 15;

FIG. 17 is a flowchart illustrating an operating method of the RF switch according to an exemplary embodiment of the present disclosure; and

FIG. 18 is a block diagram illustrating an example of a generalized controller, microcontroller, and/or a computing system capable of performing at least a part of a process shown in FIG. 17.

### DETAILED DESCRIPTION

In addition to the above objects, another objects and features of the present disclosure will become more apparent through the description of exemplary embodiments with reference to the accompanying drawings.

For a clearer understanding of the features and advantages of the present disclosure, exemplary embodiments of the present disclosure will be described in detail with reference to the accompanied drawings. However, it should be understood that the present disclosure is not limited to particular embodiments disclosed herein but includes all modifications, equivalents, and alternatives falling within the spirit and scope of the present disclosure.

The terminologies including ordinals such as “first” and “second” designated for explaining various components in this specification are used to discriminate a component from the other ones but are not intended to be limiting to a specific component. For example, a second component may be referred to as a first component and, similarly, a first component may also be referred to as a second component without departing from the scope of the present disclosure. As used herein, the term “and/or” may include a presence of one or more of the associated listed items and any and all combinations of the listed items.

In the description of exemplary embodiments of the present disclosure, “at least one of A and B” may mean “at least one of A or B” or “at least one of combinations of one or more of A and B”. In addition, in the description of exemplary embodiments of the present disclosure, “one or more of A and B” may mean “one or more of A or B” or “one or more of combinations of one or more of A and B”.

When a component is referred to as being “connected” or “coupled” to another component, the component may be directly connected or coupled logically or physically to the other component or indirectly through an object therebetween. Contrarily, when a component is referred to as being “directly connected” or “directly coupled” to another component, it is to be understood that there is no intervening object between the components. Other words used to describe the relationship between elements should be interpreted in a similar fashion.

The terminologies are used herein for the purpose of describing particular exemplary embodiments only and are not intended to limit the present disclosure. The singular forms include plural referents as well unless the context clearly dictates otherwise. Also, the expressions “comprises,” “includes,” “constructed,” “configured” are used to refer a presence of a combination of stated features, numbers, processing steps, operations, elements, or components, but are not intended to preclude a presence or addition of another feature, number, processing step, operation, element, or component.

Unless defined otherwise, all terms used herein, including technical or scientific terms, have the same meaning as commonly understood by those of ordinary skill in the art to which the present disclosure pertains. Terms such as those defined in a commonly used dictionary should be interpreted as having meanings consistent with their meanings in the context of related literatures and will not be interpreted as having ideal or excessively formal meanings unless explicitly defined in the present application.

Meanwhile, one or more conventional components may be included in a configuration of the present disclosure if necessary, and such components will be described herein to an extent that it does not obscure the technical idea and concept of the present disclosure. If the description of the conventional components may obscure the technical idea and concept of the present disclosure, however, detailed description of such components may be omitted for simplicity.

However, the present disclosure is not intended to claim rights to these known technologies, and some of the conventional technologies may be included in the description of exemplary embodiments to enable to those skilled in the art to implement the exemplary embodiments without deviating from a scope of a technical concept of the exemplary embodiments.

Exemplary embodiments of the present disclosure will now be described in detail with reference to the accompanying drawings. In the drawings, the same components may be designated by the same reference numerals to facilitate overall understanding of the disclosure, and duplicate descriptions thereof will be omitted for simplicity.

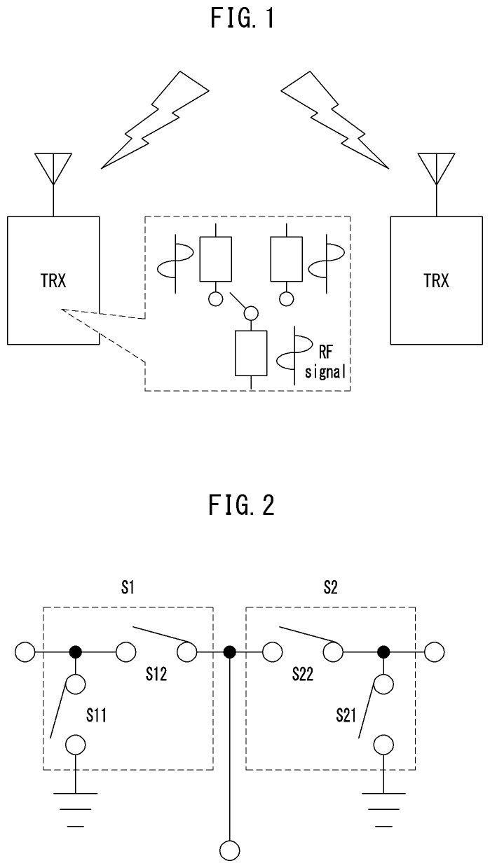

FIG. 1 is a schematic diagram illustrating roles of a radio frequency (RF) front end and an RF switch according to an exemplary embodiment of the present disclosure.

The RF front end refers to a functional block connected directly to an antenna in a wireless communications system and processing an RF signal to convert into a baseband signal.

The RF front end may perform operations including frequency conversion, filtering, amplification, and so on. The functional block of the RF front end is one of the core portions of the wireless communications system and may provide an interface between the antenna and a digital component.

The RF switch is a device for selecting a signal transmission path to effectively route the RF signal in a wireless communications system. The RF switch may be used in signal transmitting and receiving paths in a certain frequency band and may select one of several signal paths to allow a passage of the signal or to block the signal. The usages or roles of the RF switch may be summarized as follows:
Signal path selection: The RF switch may select a particular path among various antennas or transmission lines to route the signal. For example, the RF switch may select an optimal antenna in a multiple antenna system or perform a switching among a plurality of transmission lines.
Signal blocking and reinforcement: The RF switch may block or reinforce a signal in a particular path to optimize the performance of the wireless communications system. For example, the RF switch may block an unnecessary signal component an environment where a strong interference occurs or reinforce the signal to increase a communication range.
Multiple operation mode and frequency band support: The RF switch may be adapted to various communication environments to support various wireless communication modes and frequency bands. This feature of the RF switch may be especially beneficial in system using multiple frequency bands or employing multiple protocols.

These usages or roles of the RF switch may improve the performance of wireless communications system and minimize a signal interference to enable stable and efficient communications.

FIG. 2 is a schematic diagram illustrating an equivalent circuit showing a connection configuration of a conventional RF switch.

Referring to FIG. 2, the RF switch may have two different operation modes each for a transmission operation and a reception operation. During a transmission mode, two series transistors S12 and S22 are closed and two shunt transistors S11 and S21 are open. During a reception mode, the series transistors S12 and S22 are open and the shunt transistors S11 and S21 are closed. The switch structure of FIG. 2 has disadvantages of a high insertion loss and a low isolation due to parasitic capacitances of the transistors in the switch, especially at high frequencies. Since it is impossible to select sizes of the transistors forming the RF switch such that the insertion loss is reduced and the isolation is enhanced at the same time, there is a trade-off relationship between the insertion loss and the isolation.

In the circuit of FIG. 2, it is required to increase the sizes of the shunt switches S11 and S21 in order to increase the isolation of an OFF path. Meanwhile, it is required to reduce the sizes of the shunt switches S11 and S21 in order to reduce the insertion loss when the circuit of FIG. 2 is used as a portion of an ON path. Since the isolation and the insertion loss are in a trade-off relationship as such, there is a problem that it is difficult to improve both the parameters in the circuit of FIG. 2.

In the circuit of FIG. 2, it is required to reduce the sizes of the series switches S12 and S22 in order to increase the isolation of the OFF path. Meanwhile, it is required to increase the sizes of the series switches S12 and S22 in order to reduce the insertion loss when the circuit of FIG. 2 is used as a portion of the ON path. Since the isolation and the insertion loss are in a trade-off relationship as such, there is a problem that it is difficult to improve both the parameters in the circuit of FIG. 2.

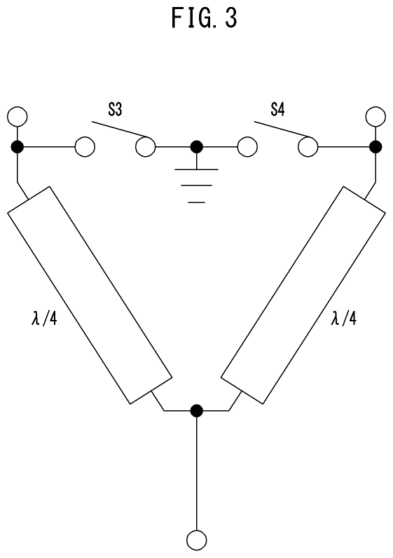

FIG. 3 is a schematic diagram illustrating a conventional switch structure employing a transmission line.

Referring to FIG. 3, a λ/4 line used for a frequency operation is a RF transmission line having a length of a quarter of a wavelength of the RF signal. A shunt transistor on a transmission side is maintained in an OPEN state during the transmission operation but is driven in the other way during the reception operation. At this time, the reception port may be recognized to be in a high-Z state in which the resistance increases infinitely due to the λ/4 line. It is impossible to select sizes of the transistors such that the insertion loss is reduced and the isolation is enhanced at the same time, there is a trade-off relationship between the insertion loss and the isolation.

It is required to increase the sizes of the shunt switches S3 and S4 in order to increase the isolation of an OFF path in the circuit of FIG. 3. Meanwhile, it is required to reduce the sizes of the shunt switches S3 and S4 in order to reduce the insertion loss when the circuit of FIG. 3 is used as a portion of an ON path. Since the isolation and the insertion loss are in a trade-off relationship as such, there is a problem that it is difficult to improve both the parameters in the circuit of FIG. 3.

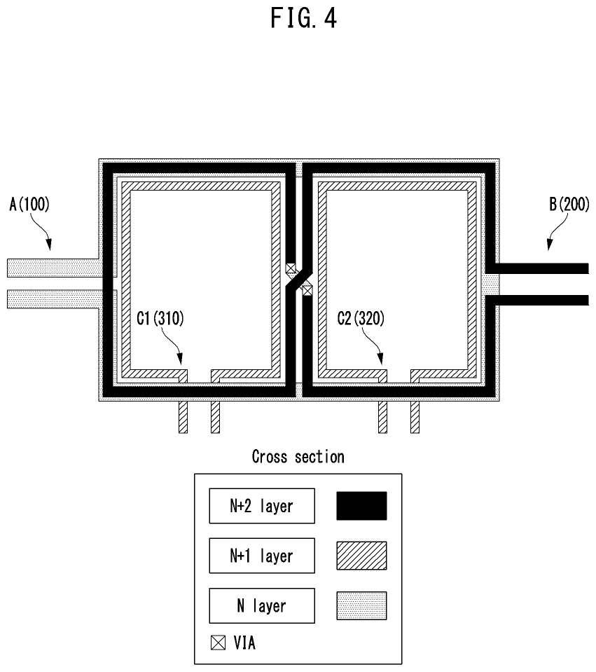

FIG. 4 is a schematic diagram illustrating an RF switch device utilizing a transformer according to an exemplary embodiment of the present disclosure.

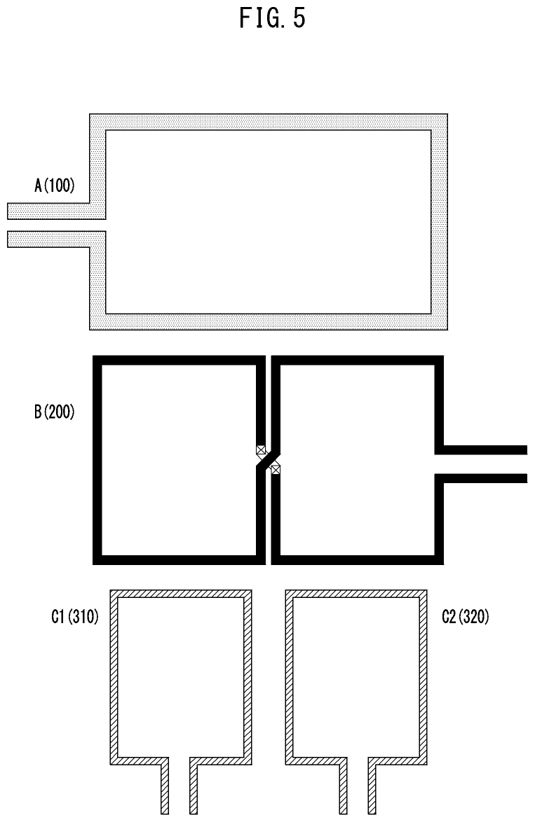

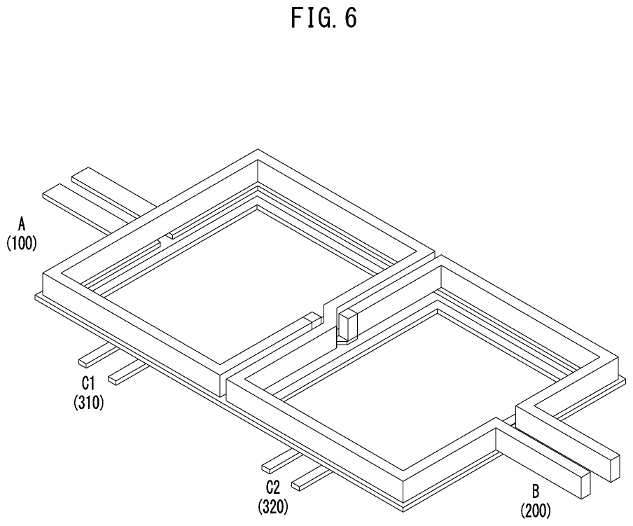

FIG. 5 is an exploded view of the RF switch device shown in FIG. 4 to facilitate understanding of a shape of each inductor element in the RF switch device.

FIG. 6 is a perspective view of the RF switch device shown in FIG. 4 to facilitate understanding of a three-dimensional shape of the RF switch device.

Referring to FIGS. 4 to 6, the RF switch device according to an exemplary embodiment of the present disclosure may include a first primary inductor (C1) 310, a second primary inductor (C2) 320, a first secondary inductor (A) 100, and a second secondary inductor (B) 200. The first primary inductor (C1) 310 and the second primary inductor (C2) 320 may be disposed on a same layer (N+1). A layer (N) of the first secondary inductor (A) 100 may be arranged to be separate from the layer (N+1) in of the primary inductors C1 and C2 and a layer (N+2) of the second secondary inductor (B) 200.

Although each of the inductor elements is disposed in the layers of N, N+1, and N+2, respectively, in the embodiment illustrated in FIGS. 4-6, it may be sufficient for each inductor element to be disposed at a different vertical position (i.e., position in the z-axis direction) in the drawings such that virtual planar sections formed by the inductor elements occupy a same or similar horizontal position (i.e., position in the xy-plane). Further, the present disclosure is not limited by the identifiers of the layers N, N+1, and N+2.

The second secondary inductor (B) 200 may have a shape of a twisted loop which is twisted to have a first loop portion positioned to match a first region covered by the first primary inductor (C1) 310 and a second loop portion positioned to match a second region covered by the second primary inductor (C2) 320, so that currents flow in opposite directions in the first loop portion and the second loop portion. Here, a via contact (not shown) may be formed in a twisted position if necessary.

The inductor elements may be arranged to be magnetically coupled to each other.

Each of the inductor elements may be disposed in a same layer as another inductor element or in a different layer from another inductor element, as long as the inductor elements are magnetically coupled to each other. However, as mentioned above, it may be desirable that the inductor elements are disposed to share the same or similar horizontal position so as to share the magnetic flux.

The first secondary inductor (A) 100 and the second secondary inductor (B) 200 are configured to have the same cross-sectional area of hollows through which magnetic flux pass. The second secondary inductor (B) 200 having the shape of the twisted loop may be configured such that the magnetic fluxes penetrating the two loop portions are formed in opposite directions when viewed from above.

The first primary inductor (C1) 310 and the second primary inductor (C2) 320 may be arranged to share magnetic fluxes with the first and second loop portions formed in the second secondary inductor (B) 200, respectively.

Between a port of the first secondary inductor (A) 100 or a port of the second secondary inductor (B) 200, one port from which the signal is output may be determined based on a direction of a current flowing through the primary inductors (C1) 310 and (C2) 320.

That is, depending on the direction of the current flowing through the primary inductors (C1) 310 and (C2) 320, it may be determined whether the primary side port C is effectively coupled (i.e., coupled enough to ensure a substantial signal transfer) with the port A or the primary side port C is effectively coupled with the port B.

Here, it is noted that the ports that are not effectively coupled to each other are isolated from each other to block the signal transfer due to a magnetic cancellation, which will be described below.

An RF switch device according to an exemplary embodiment of the present disclosure may include the primary inductors (C1) 310 and (C2) 320 forming a primary side coil of a transformer and connected to a first port (port C) 500; a first secondary inductor (A) 100 forming a part of a secondary side coil of the transformer and connected to a second port (port A) 120; and a second secondary inductor (B) 200 forming another part of the secondary side coil of the transformer and connected to a third port (port B) 130.

The primary inductors (C1) 310 and (C2) 320 may include a first primary inductor (C1) 310 covering the first region; and a second primary inductor (C2) 320 covering a second region outside the first region, respectively.

The first secondary inductor (A) 100 may form a single loop allowing a current to flow in a single direction in both the first region and the second region.

The second secondary inductor (B) 200 may have the shape of the twisted loop, as mentioned above, having the twisted portion between the first loop portion and the second loop portion, so that the current flows in opposite directions in the first loop portion corresponding to the first region and the second loop portion corresponding to the second region.

The first primary inductor (C1) 310 may be magnetically coupled with one of the first secondary inductor (A) 100 and the second secondary inductor (B) 200 in the first region, and the second primary inductor (C2) 320 may be magnetically coupled with the other one of the first secondary inductor (A) 100 and the second secondary inductor (B) 200 in the second region.

In the RF switch device according to an exemplary embodiment of the present disclosure, the direction of a first loop current flowing in the first primary inductor (C1) 310 located in the first region and the direction of a second loop current flowing in the second primary inductor (C2) 320 located in the second region may be controlled to be the same as or opposite to each other.

In the RF switch device according to an exemplary embodiment of the present disclosure, directions of a first magnetic flux formed in the first region and the direction of a second magnetic flux formed in the second region may be determined according to the directions of the first loop current and the second loop current.

In the RF switch device according to an exemplary embodiment of the present disclosure, it may be determined whether the first port (port C) 500 and the second port (port A) 120 are effectively coupled to ensure the signal transfer or whether the first port (port C) 500 and the third port (port B) 130 are effectively coupled to ensure the signal transfer, according to whether the direction of the first loop current and the direction of the second loop current are identical or opposite to each other.

The RF switch device according to an exemplary embodiment of the present disclosure may further include a switching circuit connected to the first primary inductor (C1) 310 and the second primary inductor (C2) 320 to control the direction of the first loop current and the direction of the second loop current to be identical or opposite to each other.

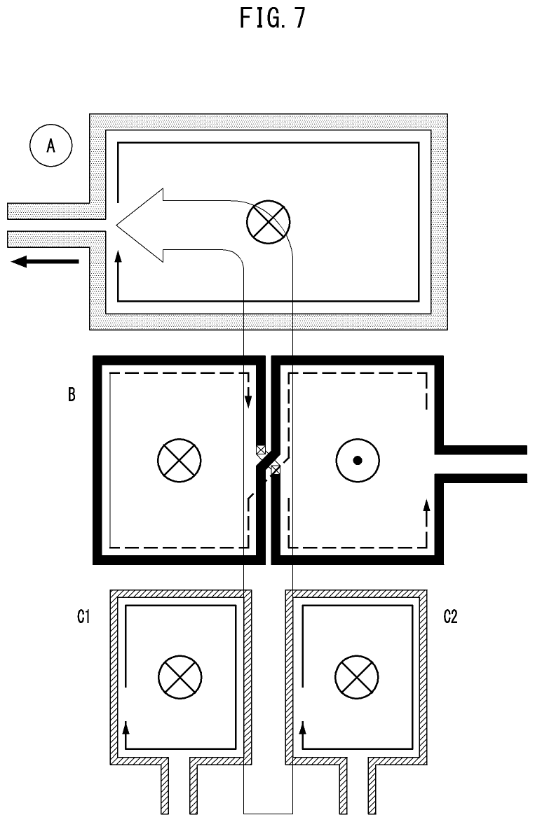

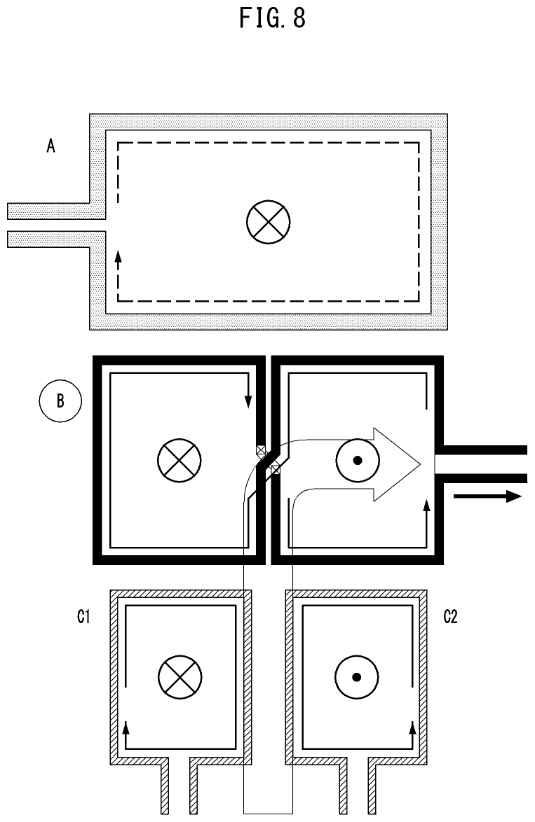

FIGS. 7 and 8 shows examples in which the directions of the currents flowing through the first primary inductors (C1) 310 and the second primary inductor (C2) 320 are controlled to determine or change a signal path in the RF switch, that is, whether to output the signal in the direction of the port A of the first secondary inductor (A) 100 or in the direction of the port B of the second secondary inductor (B) 200 according to the directions of the currents flowing through the first primary inductors (C1) 310 and the second primary inductor (C2) 320.

FIG. 7 is a conceptual diagram illustrating a first embodiment of an operation of the RF switch device according to an exemplary embodiment of the present disclosure, in which the loop current directions (or switching polarities) of the first primary inductor (C1) 310 and the second primary inductor (C2) 320 are the same as each other and a signal is input through the primary side port.

Referring to FIG. 7, when the directions of the first loop current and the second loop current are the same as each other, the direction of the first magnetic flux formed in the first region by the first loop current and the direction of the second magnetic flux formed in the second region by the second loop current may be the same as each other.

In this case, a current component induced in the first secondary inductor (A) 100 by the first loop current and a current component induced in the first secondary inductor (A) 100 by the second loop current may be constructively superposed.

At this time, the first port (port C) 500 and the second port (port A) 120 may be magnetically linked through a constructive coupling. That is, the first port (port C) 500 and the second port (port A) 120 may be effectively coupled to allow a substantial transfer of the signal between the first port (port C) 500 and the second port (port A) 120.

Meanwhile, the current component induced in the second secondary inductor (B) 200 by the first loop current and the current component induced in the second secondary inductor (B) 200 by the second loop current may be destructively superposed and cancelled. As a result, regardless of the signal input or induced in the first port (port C) 500, there will be no input or output signal passing through the third port (port B) 130, and the first port (port C) and the third port (port B) 130 may be isolated so that no signal is transmitted between them.

In the RF switch device according to an exemplary embodiment of the present disclosure, in a state that the direction of the first loop current and the direction of the second loop current are determined, an input signal may be applied through the first port (port C) 500, and a signal may be output through the second port (port A) 120 or the third port (port B) 130. In the first embodiment shown in FIG. 7, when the input signal is applied through the first port (port C) 500, a signal induced by a mutual induction may be output through the second port (port A) 120.

FIG. 8 is a conceptual diagram illustrating a second embodiment of an operation of the RF switch device according to an exemplary embodiment of the present disclosure, in which the loop current directions (or switching polarities) of the first primary inductor (C1) 310 and the second primary inductor (C2) 320 are opposite to each other and a signal is input through the primary side port.

Referring to FIG. 8, when the directions of the first loop current and the second loop current are opposite to each other, the direction of the first magnetic flux formed in the first region by the first loop current and the direction of the second magnetic flux formed in the second region by the second loop current may be opposite to each other.

In this case, the current component induced in the first secondary inductor (A) 100 by the first loop current and the current component induced in the first secondary inductor (A) 100 by the second loop current may be destructively superposed and cancelled.

As a result, regardless of the signal input or induced in the first port (port C) 500, there will be no input or output signal passing through the second port (port A) 120, and the first port (port C) and the second port (port A) 120 may be isolated so that no signal is transmitted between them.

At this time, the current component induced in the second secondary inductor (B) 200 by the first loop current and the current component induced in the second secondary inductor (B) 200 by the second loop current may be constructively superposed.

Thus, the first port (port C) 500 and the third port (port B) 130 may be magnetically linked through the constructive coupling. That is, the first port (port C) 500 and the third port (port B) 130 may be effectively coupled to allow a substantial transfer of the signal between the first port (port C) 500 and the third port (port B) 130.

In the RF switch device according to an exemplary embodiment of the present disclosure, in a state that the direction of the first loop current and the direction of the second loop current are determined, the input signal may be applied through the first port (port C) 500, and a signal may be output through the second port (port A) 120 or the third port (port B) 130. In the second embodiment shown in FIG. 8, when the input signal is applied through the first port (port C) 500, the signal induced by the mutual induction may be output through the third port (port B) 130.

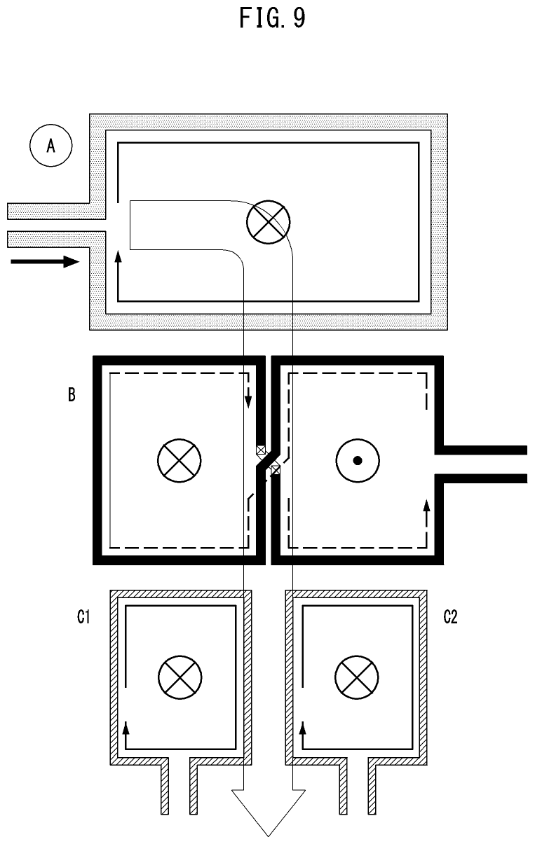

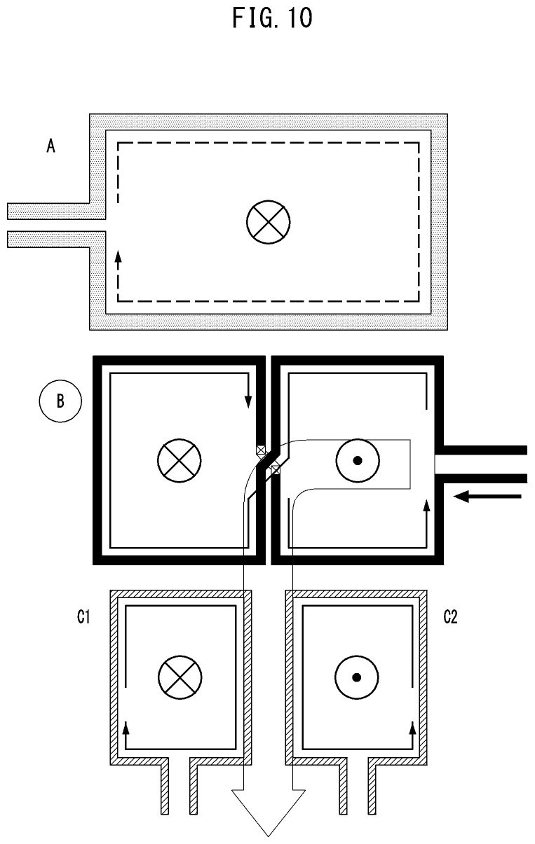

FIGS. 9 and 10 shows examples in which whether to input the signal through the port A of the first secondary inductor (A) 100 or through the port B of the second secondary inductor (B) 200 may be determined, and then polarities of the first primary inductor (C1) 310 and the second primary inductor (C2) 320 are selected to control the directions of the currents flowing through the first primary inductors (C1) 310 and the second primary inductor (C2) 320.

FIG. 9 is a conceptual diagram illustrating a third embodiment of an operation of the RF switch device according to an exemplary embodiment of the present disclosure, in which the loop current directions (or switching polarities) of the first primary inductor (C1) 310 and the second primary inductor (C2) 320 are the same as each other and the input signal is applied through the secondary side port.

Referring to FIG. 9, when the polarities of the first primary inductor (C1) 310 and the second primary inductor (C2) 320 are the same as each other, the current flowing in the first secondary inductor (A) 100 forms magnetic fluxes of the same direction in the first region covered by the first primary inductor (C1) 310 and the second region covered by the second primary inductor (C2) 320, and currents of the same direction may be induced in the first primary inductor (C1) 310 and the second primary inductor (C2) 320.

That is, the direction of the first loop current induced in the first primary inductor (C1) 310 may be the same as the direction of the second loop current induced in the second primary inductor (C2) 320.

Therefore, in the present embodiment, when the polarities of the first primary inductor (C1) 310 and the second primary inductor (C2) 320 are the same as each other, the first port (port C) 500 and the second port (port A) 120 may be effectively magnetically coupled.

In this case, even if there is a current flowing in the second secondary inductor (B) 200, a magnetic flux formed by this current in the first region and the second region may induce the first and the second loop current components in the first primary inductor (C1) 310 and the second primary inductor (C2) 320, respectively, in the opposite direction. The first and the second loop current components induced in the first primary inductor (C1) 310 and the second primary inductor (C2) 320 may be added externally and canceled. Meanwhile, currents induced in the first secondary inductor (A) 100 by the currents flowing in the two loop portions of the second secondary inductor (B) 200 may be canceled. Thus, the second secondary inductor (B) 200 may be substantially isolated from the primary inductors (C1) 310 and (C2) 320 as well as the first secondary inductor (A) 100.

In the RF switch device according to an exemplary embodiment of the present disclosure, in a state that the direction of the first loop current and the direction of the second loop current are determined, the input signal applied through the second port (port A) 120 or the third port (port B) 130 may be output through the first port (port C) 500. In the third embodiment shown in FIG. 9, the signal input through the second port (port A) 120 may be output through the first port (port C) 500.

FIG. 10 is a conceptual diagram illustrating a fourth embodiment of an operation of the RF switch device according to an exemplary embodiment of the present disclosure, in which the loop current directions (or switching polarities) of the first primary inductor (C1) 310 and the second primary inductor (C2) 320 are opposite to each other and the input signal is applied through the secondary side port.

Referring to FIG. 10, since the directions of the currents are opposite in the first loop portion and the second loop portion of the second secondary inductor (B) 200, the magnetic flux formed in the first region covered by the first primary inductor (C1) 310 according to the current flowing in the first loop portion of the second secondary inductor (B) 200 is opposite to the magnetic flux formed in the second region covered by the second primary inductor (C2) 320 according to the current flowing in the second loop portion of the second secondary inductor (B) 200. Accordingly, currents of the opposite direction may be induced in the first primary inductor (C1) 310 and the second primary inductor (C2) 320.

That is, the direction of the first loop current induced in the first primary inductor (C1) 310 may be opposite to the direction of the second loop current induced in the second primary inductor (C2) 320.

Since, however, the polarities of the first primary inductor (C1) 310 and the second primary inductor (C2) 320 are opposite to each other, the first loop current induced in the first primary inductor (C1) 310 may be constructively superimposed on the second loop current induced in the second primary inductor (C2) 320, and the first port (port C) 500 and the third port (port B) 130 may be effectively magnetically coupled.

In this case, even if there is a current flowing in the first secondary inductor (A) 100, a magnetic flux formed by this current in the first region and the second region may induce the first and the second loop current components in the first primary inductor (C1) 310 and the second primary inductor (C2) 320, respectively, in the same direction. The first and the second loop current components induced in the first primary inductor (C1) 310 and the second primary inductor (C2) 320 of the opposite polarities may be added externally and canceled. Meanwhile, currents induced in the two loop portions of the second secondary inductor (B) 200 by the current flowing in the first secondary inductor (A) 100 may be canceled. Thus, the first secondary inductor A (200) may be substantially isolated from the primary inductors (C1) 310 and (C2) 320 as well as the second secondary inductor (B) 200.

In the RF switch device according to an exemplary embodiment of the present disclosure, in a state that the direction of the first loop current and the direction of the second loop current are determined, the input signal applied through the second port (port A) 120 or the third port (port B) 130 may be output through the first port (port C) 500. In the fourth embodiment shown in FIG. 10, the signal input through the third port (port B) 130 may be output through the first port (port C) 500.

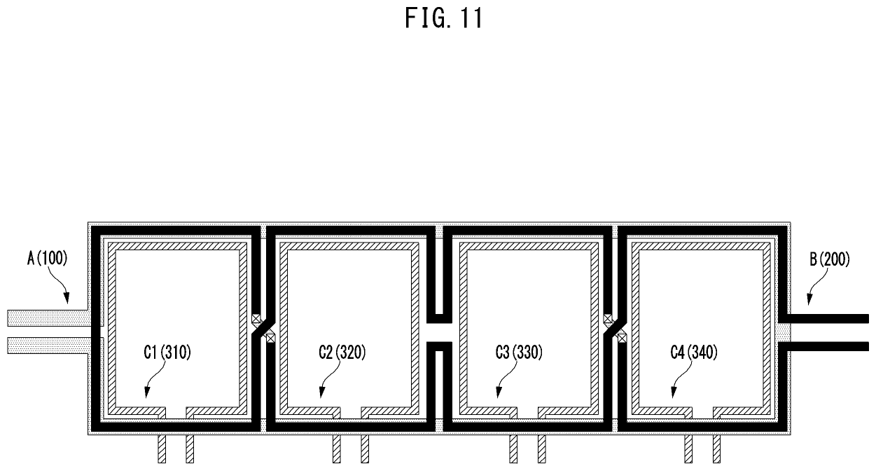

FIG. 11 is a conceptual diagram illustrating the RF switch device according to another exemplary embodiment of the present disclosure, in which a number of segments in a primary inductor is increased to enhance the power coupling between the inductors.

Referring to FIG. 11, in the RF switch device according to the present embodiment may further include a third primary inductor (C3) 330 covering a third region other than the first region and the second region and a fourth primary inductor (C4) 340 covering a fourth region other than the first through third regions.

The first secondary inductor (A) 100 may be arranged to cover the first through the fourth regions.

The second secondary inductor (B) 200 may have an additional twisted position between the third region and the fourth region so that current flows in the third region may be opposite to the current flowing in the fourth region.

In the embodiment of FIG. 11, the increase in a number of primary inductor segments may enhance the power coupling between the inductors.

Although the RF switch device according to the embodiment illustrated in FIG. 11 includes four primary inductor segments for enhancing the power coupling, the spirit of the present disclosure is not limited to the exemplary embodiment. In another alternative embodiments of the present disclosure, additional inductor segments may be added within the spirit of the present disclosure.

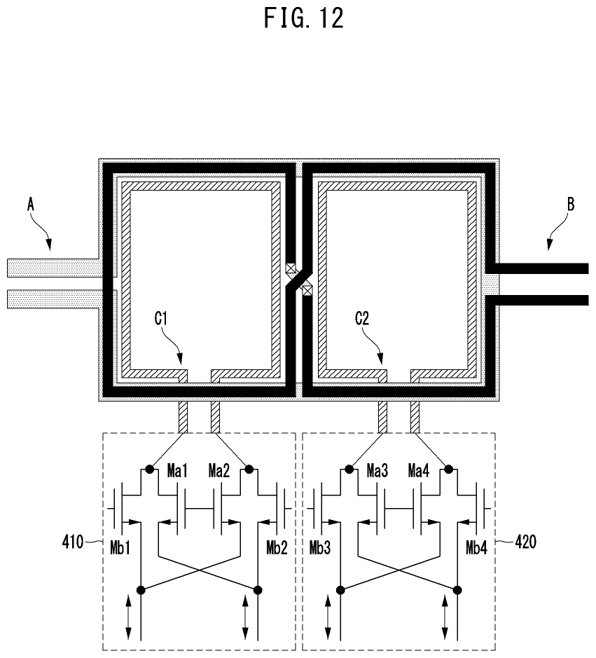

FIG. 12 is a conceptual diagram illustrating the RF switch device according to an exemplary embodiment of the present disclosure, in which switching circuits connecting the primary inductor segments to the primary side port are incorporated.

The RF switch device according to the present embodiment may further include the switching circuits 410 and 420 connected to the first primary inductor (C1) 310 and the second primary inductor (C2) 320, respectively, to set the polarities of the first primary inductor (C1) 310 and the second primary inductor (C2) 320 or the directions of the first loop current and the second loop current to be the same as or opposite to each other.

In more detail, the switching circuits may include a first switching circuit 410 capable of switching a connection polarity between the first port (port C) 500 and the first primary inductor (C1) 310; and a second switching circuit 420 capable of switching the connection polarity between the first port (port C) 500 and the second primary inductor (C2) 320. The first switching circuit 410 may include a first transistor pair consisting of two transistors Ma1 and Mb1 and a second transistor pair consisting of transistors Ma2 and Mb2. The second switching circuit 420 may include a third transistor pair consisting of transistors Ma3 and Mb3 and a fourth transistor pair consisting of transistors Ma4 and Mb4.

In the RF switch device according to an exemplary embodiment of the present disclosure, when the switching circuits 410 and 420 are in a first connection state, the polarities of the first primary inductor (C1) 310 and the second primary inductor (C2) 320 may be set to be the same as each other.

In an example of the first connection state, the transistors Mb1 and Mb2 in the first switching circuit 410 may be turned on and the transistors Ma1 and Ma2 may be turned off, while the transistors Mb3 and Mb4 in the second switching circuit 420 may be turned on and the transistors Ma3 and Ma4 may be turned off.

In the RF switch device according to an exemplary embodiment of the present disclosure, when the switching circuits 410 and 420 are in a second connection state, the polarities of the first primary inductor (C1) 310 and the second primary inductor (C2) 320 may be set to be opposite to each other.

In an example of the second connection state, the transistors Mb1 and Mb2 in the first switching circuit 410 may be turned on and the transistors Ma1 and Ma2 may be turned off, while the transistors Mb3 and Mb4 in the second switching circuit 420 may be turned off and the transistors Ma3 and Ma4 may be turned on.

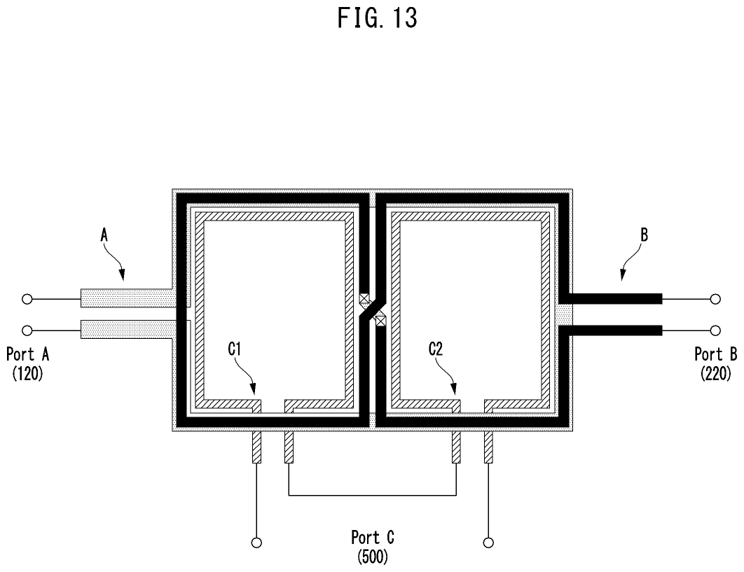

FIG. 13 is a conceptual diagram illustrating a connection configuration between the primary inductor segments compatible with the first embodiment and the third embodiment of the operation of the RF switch device of the present disclosure.

The first connection state between the primary inductor segments, i.e., the first primary inductor (C1) 310 and the second primary inductor (C2) 320, is equivalently illustrated in FIG. 13.

In the RF switch device according to an exemplary embodiment of the present disclosure, when the switching circuits are in the first connection state, reference directions of the first loop current and the second loop current may be set to be identical to each other.

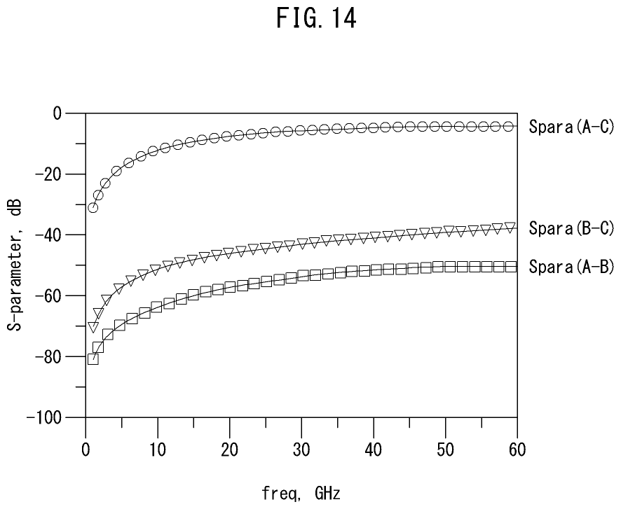

FIG. 14 is a graph showing results of electromagnetic simulations according to frequency bands for the embodiment of FIG. 13.

In FIG. 14, a curve representing S-parameters, Spara(A-B), shows that a high isolation performance of 50 dB is provided between the port A and the port B regardless of the connection in the port C.

A curve representing S-parameters, Spara(A-C), shows that a low insertion loss of 5 dB is provided for the port A corresponding to the first secondary inductor (A) 100 in which the direction of the magnetic flux is the same as the directions of the magnetic fluxes in the first primary inductor (C1) 310 and the second primary inductor (C2) 320.

A curve representing S-parameters, Spara(B-C), shows that a high isolation performance of 40 dB is provided for the port B corresponding to the second secondary inductor (B) 200 in which the direction of the magnetic flux is not identical to the directions of the magnetic fluxes in the first primary inductor (C1) 310 and the second primary inductor (C2) 320.

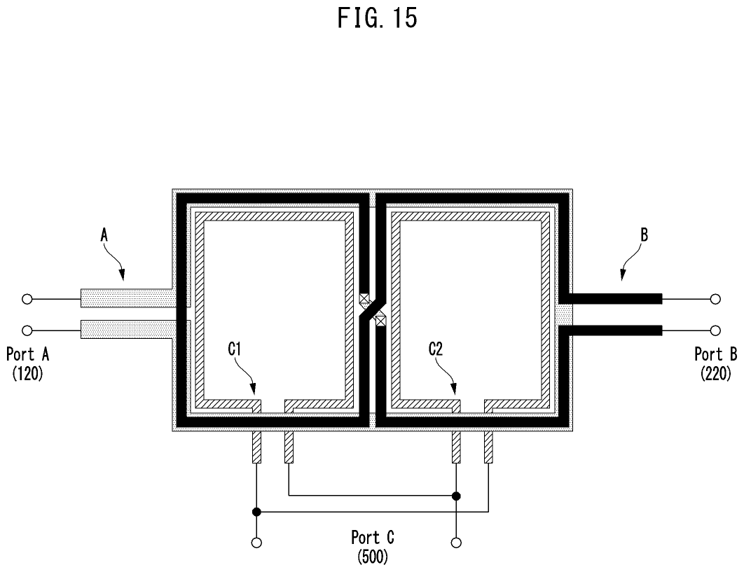

FIG. 15 is a conceptual diagram illustrating a connection configuration between the primary inductor segments compatible with the second embodiment and the fourth embodiment of the operation of the RF switch device of the present disclosure.

The second connection state between the primary inductor segments, i.e., the first primary inductor (C1) 310 and the second primary inductor (C2) 320, is equivalently illustrated in FIG. 15.

In the RF switch device according to an exemplary embodiment of the present disclosure, when the switching circuits are in the second connection state, reference directions of the first loop current and the second loop current may be set to be opposite to each other.

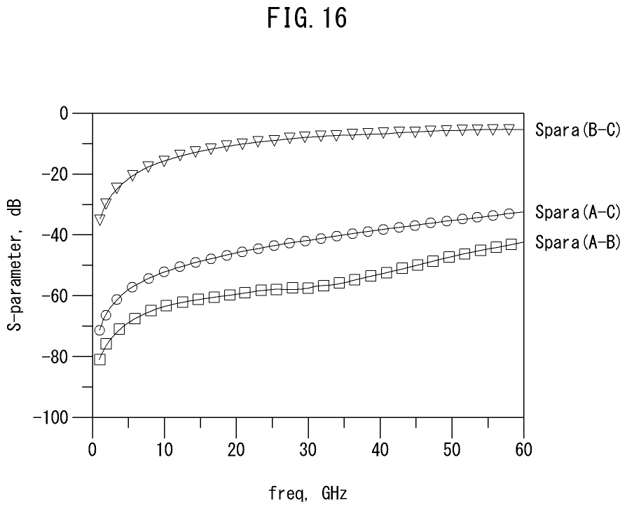

FIG. 16 is a graph showing results of electromagnetic simulations according to frequency bands for the embodiment of FIG. 15.

In FIG. 16, a curve representing S-parameters Spara(A-B) shows that a high isolation performance of 50 dB is provided between the port A and the port B regardless of the connection in the port C.

A curve representing S-parameters, Spara(B-C), shows that a low insertion loss of 5 dB is provided for the port B corresponding to the second secondary inductor (B) 200 in which the directions of the magnetic fluxes in the first region and the second region are the same as the directions of the magnetic fluxes in the first primary inductor (C1) 310 and the second primary inductor (C2) 320, respectively

A curve representing S-parameters, Spara(A-C), shows that a high isolation performance of 40 dB is provided for the port A corresponding to the first secondary inductor (A) 100 in which the direction of the magnetic flux is not identical to the directions of the magnetic fluxes in the first primary inductor (C1) 310 and the second primary inductor (C2) 320.

Referring to the embodiments of FIGS. 13-16, it is found that insertion loss and isolation do not have a trade-off relationship in the RF switch device according to the present disclosure.

That is, the RF switch device may have characteristics of revealing a low insertion loss performance while showing a high isolation.

According to another embodiment of the present disclosure, when a MOS transistor may be connected to the port C and the structure of the RF switch of the present disclosure is used as a load or an input matching stage of an amplifier, the RF switch may further perform an amplification function.

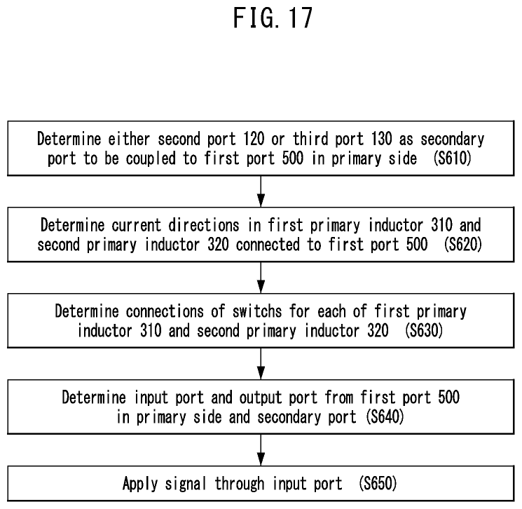

FIG. 17 is a flowchart illustrating an operating method of the RF switch according to an exemplary embodiment of the present disclosure.

The method of operating the RF switch according to an exemplary embodiment of the present disclosure may include: selecting either the second port (port A) 120 connected to the first secondary inductor (A) 100 or the third port (port B) 130 connected to the second secondary inductor (B) 200 as a secondary side port to be magnetically coupled to the primary inductors (C1, C2) 310 and 320 forming the primary coil of a transformer and connected to the first port (port C) 500 (S610); determining the polarities or the directions of the first loop current and the second loop current flowing in the first primary inductor (C1) 310 and the second primary inductor (C2) 320, respectively, connected to the first port (port C) 500 and included in the primary inductors (C1, C2) 310 and 320 based on the selected secondary side port (S620); and determining the input port and the output port from the first port (port C) 500 and the selected secondary side port (S640).

In the method of operating the RF switch according to an exemplary embodiment of the present disclosure, the first primary inductor (C1) 310 may cover the first region, and the second primary inductor (C2) 320 may cover the second region. The first secondary inductor (A) 100 may cover both the first region and the second region so that a loop current through the first secondary inductor (A) 100 flows with a same direction in the first region and the second region. The second secondary inductor (B) 200 may have the shape of the twisted loop which has the twisted position between the first region and the second region so that the current flows in opposite directions in the first loop portion covering the first region and the second loop portion covering the second region.

The operation (S620) of determining the polarities or the directions of the first loop current and the second loop current may include: when the second port (port A) 120 is selected as the secondary side port, the directions of the first loop current and the second loop current are set to be the same as each other; and when the third port (port B) 130 is selected as the secondary side port, the directions of the first loop current and the second loop current are set to be opposite to each other.

The method of operating the RF switch according to an exemplary embodiment of the present disclosure may further include an operation (S630) of determining a configuration for connecting the first primary inductor (C1) 310 and the second primary inductor (C2) 320 according to the directions of the first loop current and the second loop current.

The operation (S630) of determining the configuration for connecting the first primary inductor (C1) 310 and the second primary inductor (C2) 320 may include: determining a connection state of the first switching circuit connecting the first port (port C) 500 and the first primary inductor (C1) 310; and determining a connection status of the second switching circuit connecting the first port (port C) 500 and the second primary inductor (C2) 320.

The method of operating the RF switch according to an exemplary embodiment of the present disclosure may further include an operation (S650) of applying a signal to the input port.

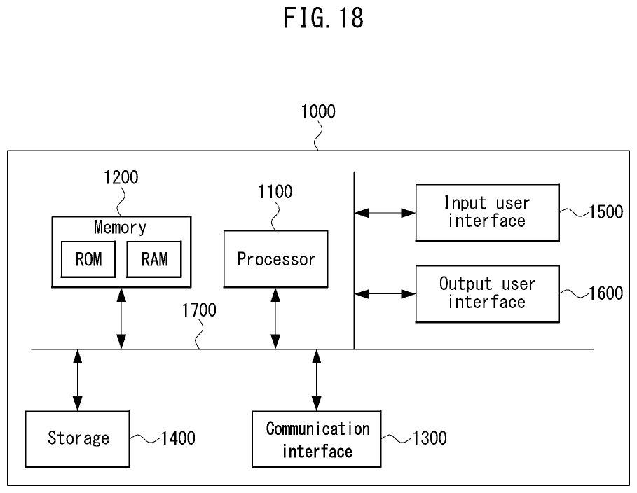

FIG. 18 is a block diagram illustrating an example of a generalized controller, microcontroller, and/or a computing system capable of performing at least a part of the process shown in FIG. 17.

Referring to FIG. 18, the computing system 1000 according to an embodiment of the present disclosure may be configured to include a processor 1100, a memory 1200, a communication interface 1300, a storage device 1400, an input interface 1500, an output interface 1600, and a bus 1700.

The computing system 1000 according to an embodiment of the present disclosure may include at least one processor 1100 and the memory 1200 storing program instructions instructing the at least one processor 1100 to perform at least one process step. At least some of the operations or process steps of the method according to an embodiment of the present disclosure may be performed by the at least one processor 1100 loading and executing the program instructions from the memory 1200.

The processor 1100 may include a central processing unit (CPU) or a graphics processing unit (GPU) or may be implemented by another kind of dedicated processor suitable for performing the method of the present disclosure.

Each of the memory 1200 and the storage device 1400 may be comprised of at least one of a volatile storage medium and a non-volatile storage medium. For example, the memory 1200 may be comprised of at least one of a read only memory (ROM) and a random access memory (RAM).

Additionally, the computing system 1000 may include the communication interface 1300 performing communications through a wireless communication network.

Additionally, the computing system 1000 may further include the storage device 1400, the input interface 1500, and the output interface 1600.

The components of the computing system 1000 may be connected to each other by the system bus 1700 to communicate with each other.

The computing system 1000 according to an exemplary embodiment of the present disclosure may be any data processing device capable of communications through a network such as a desktop computer, a laptop computer, a notebook PC, a smartphone, a tablet PC, a mobile phone, a smart watch, smart glasses, an e-book reader, a portable multimedia player (PMP), a portable game console, a navigation device, a digital camera, a digital multimedia broadcasting (DMB) player, a digital audio recorder, a digital audio player, a digital video recorder, a digital video player, and a personal digital assistant (PDA).

The method according to exemplary embodiments of the present disclosure can be implemented by computer-readable program codes or instructions stored on a computer-readable intangible recording medium. The computer-readable recording medium includes all types of recording device storing data which can be read by a computer system. The computer-readable recording medium may be distributed over computer systems connected through a network so that the computer-readable program or codes may be stored and executed in a distributed manner. The computer-readable recording medium may include a hardware device specially configured to store and execute program instructions, such as a ROM, RAM, and flash memory. The program instructions may include not only machine language codes generated by a compiler, but also high-level language codes executable by a computer using an interpreter or the like.

Some aspects of the present disclosure described above in the context of the device may indicate corresponding descriptions of the method according to the present disclosure, and the blocks or devices may correspond to operations of the method or features of the operations. Similarly, some aspects described in the context of the method may be expressed by features of blocks, items, or devices corresponding thereto. Some or all of the operations of the method may be performed by (or using) a hardware device such as a microprocessor, a programmable computer, or electronic circuits, for example. In some exemplary embodiments, one or more of the most important operations of the method may be performed by such a device.

In some exemplary embodiments, a programmable logic device such as a field-programmable gate array may be used to perform some or all of functions of the methods described herein. In some exemplary embodiments, the field-programmable gate array may be operated with a microprocessor to perform one of the methods described herein. In general, the methods are preferably performed by a certain hardware device.

The description of the disclosure may be merely exemplary in nature and, thus, variations that do not depart from the substance of the disclosure may be intended to be within the scope of the disclosure. Such variations may not be to be regarded as a departure from the spirit and scope of the disclosure. Thus, it will be understood by those of ordinary skill in the art that various changes in form and details may be made without departing from the spirit and scope as defined by the following claims.

What is claimed is:

1. An RF switch device, comprising:
a primary inductor forming a primary coil of a transformer and connected to a first port;
a first secondary inductor forming a part of a secondary coil of the transformer and connected to a second port; and
a second secondary inductor forming another part of the secondary coil of the transformer and connected to a third port,
wherein the primary inductor comprises:
a first primary inductor covering a first region; and
a second primary inductor covering a second region other than the first region,
wherein the second secondary inductor has a twisted position between the first region and the second region so that a current flows in different directions in a first loop portion covering the first region and a second loop portion covering the second region.

2. The RF switch device as claimed in claim 1, wherein the first primary inductor is magnetically coupled to either the first secondary inductor or the second secondary inductor in the first region,
wherein the second primary inductor is magnetically coupled to either the first secondary inductor or the second secondary inductor in the second region.

3. The RF switch device as claimed in claim 1, wherein a direction of a first loop current formed in the first region by the first primary inductor and a direction of a second loop current formed in the second region by the second primary inductor are controlled to be the same as or opposite to each other.

4. The RF switch device as claimed in claim 3, wherein directions of a first magnetic flux formed in the first region and a second magnetic flux formed in the second region are determined according to the direction of the first loop current and the direction of the second loop current, respectively.

5. The RF switch device as claimed in claim 3, wherein the first port is effectively coupled with either the second port or the third port for a signal passage depending on whether the directions of the first loop current and the second loop current are the same as each other or opposite to each other.

6. The RF switch device as claimed in claim 5, wherein, when the directions of the first loop current and the second loop current are the same as each other, a current component induced in the second secondary inductor by the first loop current and a current component induced in the second secondary inductor by the second loop current are canceled, and the first port is effectively coupled with the second port for the signal passage.

7. The RF switch device as claimed in claim 5, wherein, when the directions of the first loop current and the second loop current are opposite to each other, a current component induced in the first secondary inductor by the first loop current and a current component induced in the first secondary inductor by the second loop current are canceled, and the first port is effectively coupled with the third port for the signal passage.

8. The RF switch device as claimed in claim 3, further comprising:
a switching circuit connected to the first primary inductor and the second primary inductor to control the directions of the first loop current and the second loop current to be the same as each other or opposite to each other.

9. The RF switch device as claimed in claim 8, wherein the directions of the first loop current and the second loop current are controlled to be the same as each other when the switching circuit is in a first connection state.

10. The RF switch device as claimed in claim 8, wherein the directions of the first loop current and the second loop current are controlled to be opposite to each other when the switching circuit is in a second connection state.

11. The RF switch device as claimed in claim 8, wherein the switching circuit comprises:
a first switching circuit configured to switch a connection polarity between the first port and the first primary inductor; and
a second switching circuit configured to switch a connection polarity between the first port and the second primary inductor.

12. The RF switch device as claimed in claim 1, wherein the primary inductor further comprises:
a third primary inductor covering a third region other than the first region and the second region; and
a fourth primary inductor covering a fourth region other than the first through the third regions,
wherein the first secondary inductor covers the first through the fourth regions,
wherein the second secondary inductor has a shape of having another twisted position between the third region and the fourth region so that a current flows in different directions in the third region and the fourth region.

13. The RF switch device as claimed in claim 3, wherein, in a state that the directions of the first loop current and the second loop current are determined, an input signal is applied to the first port and an output signal is provided through the second port or the third port.

14. The RF switch device as claimed in claim 3, wherein, in a state that the directions of the first loop current and the second loop current are determined, an input signal is applied to the second port or the third port and an output signal is provided through the first port.

15. A method of operating an RF switch, comprising:
selecting either a second port connected to a first secondary inductor or a third port connected to a second secondary inductor as a secondary side port to be effectively coupled for a signal passage to a primary inductor forming a primary coil of a transformer and connected to a first port;
determining a direction of a first loop current flowing in a first primary inductor and a direction of a second loop current flowing in a second primary inductor based on the selected secondary side port, wherein the first primary inductor and the second primary inductor connected to the first port and included in the primary inductor; and
determining an input port and an output port from the first port and the selected secondary side port.

16. The method of claim 15, wherein the first primary inductor covers a first region, and the second primary inductor covers a second region,
wherein the second secondary inductor has a twisted position between the first region and the second region so that the current flows in opposite directions in a first loop portion covering the first region and a second loop portion covering the second region.

17. The method of claim 15, wherein determining the directions of the first loop current and the second loop current comprises:
when the second port is selected as the secondary side port, setting the directions of the first loop current and the second loop current to be the same as each other; and
when the third port is selected as the secondary side port, setting the directions of the first loop current and the second loop current to be opposite to each other.

18. The method of claim 16, further comprising:
determining a configuration for connecting the first primary inductor and the second primary inductor according to the directions of the first loop current and the second loop current.

19. The method of claim 18, wherein determining the configuration for connecting the first primary inductor and the second primary inductor comprises:
determining a connection state of a first switching circuit connecting the first port and the first primary inductor; and
determining a connection state of a second switching circuit connecting the second port and the second primary inductor.

20. The method of claim 15, further comprises:
applying a signal to the input port.
